(19) United States
(12) Patent Application Publication
(10) Pub. No.: US 2006/0083059 A1
(43) Pub. Date: Apr. 20, 2006

(54) Semiconductor device, reset control system and memory reset method

(75) Inventor: Osamu Matsuura, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/249,453

(22) Filed: Oct. 14, 2005

Related U.S. Application Data
(63) Continuation of application No. PCT/JP03/04946, filed on Apr. 17, 2003.

(51) Int. Cl. G11C 16/04

(52) U.S. Cl. 365/185.01

(57) ABSTRACT

In a semiconductor device comprising a non-volatile memory, a reset input control circuit is provided not to supply the reset signal to the non-volatile memory even when the reset signal is supplied from the external side while the BUSY/READY signal from the non-volatile memory is activated. With the reset input control circuit, over-erase of the non-volatile memory can e prevented because reset is never conducted while the non-volatile memory executes the erase process.

### TECHNICAL FIELD

The present invention relates to a semiconductor device mounting an electrically erasable and programmable non-volatile memory.

### BACKGROUND ART

Unlike the DRAM (Dynamic Random Access Memory) and SRAM (Static Random Access Memory) or the like which are semiconductor memories requiring the backup power supply, a non-volatile memory does not erase data even if the power supply fails. In recent years, a non-volatile memory, particularly a flash ROM (Read Only Memory) is widely used, because of its characteristic, into a mobile phone and a HDD, expanding its application field.

A gate of memory cell of the a non-volatile memory is formed in the double-layer structure of a control gate and a floating gate. Data can be written by implanting electrons to the floating gate and data can also be erased by discharging the electrons from the floating gate. Discharging of charges for erasing the data is conducted, in more practical, by applying negative charges to the control gate after the negative charges are implanted to the floating gate. If reset is triggered during such data erasing process, the data erasing process is interrupted forcibly, and thereby address of the non-volatile memory changes, resulting in the problem that a part of the memory cell of the non-volatile memory shows over-erase condition. Therefore, reset during the data erasing process is inhibited for the non-volatile memory.

FIG. 1 illustrates a an electronic device of the related art in which the non-volatile memory disclosed in the JP-A No. 1994-341884 is mounted. In the electronic device of the related art, a microcomputer and a non-volatile memory EEPROM 31 are mounted and moreover a reset input-control circuit 400 is also mounted. The reset input control circuit 400 is provided to prevent that data is erroneously written into the EEPROM 31 based on careless reset of the microcomputer 30 and data is erroneously erased by the EEPROM 31.

Namely, the reset input control circuit 400 does not supply the reset signal to a reset terminal 30rs of the microcomputer 30 even when the reset switch 41 for resetting the microcomputer 30 is depressed when the chip select signal Scs indicating selection of the EEPROM 31 is activated.

However, in the electronic device of the related art illustrated in FIG. 1, reset is inhibited when the EEPROM 31 is selected. Accordingly, when the EEPROM 31 is selected for the erase process, it is impossible to prevent that erroneous reset is inputted to the EEPROM 31.

FIG. 2 illustrated an information processing apparatus of the related art in which the flash ROM disclosed in the JP-A 1997-288530 is mounted. In the related information processing apparatus, a CPU 1 and a flash ROM 4 are mounted and moreover a reset delay circuit 8 is also mounted. The CPU 1 supervises whether the reset signal is inputted or not. When the reset input is detected, the erase process of flash ROM is suspended. Since the reset delay circuit 8 supplies the delayed reset signal to the CPU 1, the CPU 1 can reserve a delay time for suspending the erase process before commencing the actual reset operation.

However, in the information processing apparatus of the related art illustrated in FIG. 2, since the erase process of the flash ROM can be suspended when the CPU has recognized the reset input, it cannot be adapted to the automatic erase (cells existing in the predetermined scope are erased automatically) in which the erase process cannot be suspended. Moreover, the CPU is always required to supervise the reset input and the load thereof becomes very large.

In the related art described above, reset input to the flash ROM cannot be prevented effectively during the erase process of the flash ROM. Particularly in the electronic device comprising the flash ROM, the reset signal of the flash ROM is often used in common with the reset signal of CPU. Therefore, the flash ROM probably executes the reset process during the erase process to a large extent by erroneously considering the reset signal to the CPU as that to the own memory. As explained above, the flash ROM which has been reset during the erase process can no longer execute the re-writing process because of over-erase process. Therefore, the electronic device comprises, as a result, a defective flash ROM and becomes the defective electronic device.

### DISCLOSURE OF THE INVENTION

In view of solving the problems explained above, the present invention provides a semiconductor device which is characterized in comprising a non-volatile memory and a reset input control circuit for supplying the reset signal to the non-volatile memory and is also characterized in that the reset input control circuit does not supply the reset signal to the non-volatile memory when the busy signal outputted from the non-volatile memory is activated.

FIG. 3 is the principle diagram of the present invention.

A semiconductor device 1 in the present invention is constituted not to supply the reset signal RSTEX when a non-volatile memory 4 is conducting the erase process.

The semiconductor device 1 is formed of an external reset terminal 2, a reset input control circuit 3, a non-volatile memory 4, and a command control circuit 5.

The reset input control circuit 3 receives the reset signal from the external reset terminal 2 and supplies the reset signal RSTEX to the non-volatile memory 4.

The non-volatile memory 4 executes the reset on the basis of the reset signal from the reset input control circuit 3. Moreover, the non-volatile memory 4 supplies the BUSY/READY signal to the reset input control circuit 3. The BUSY/READY signal is activated during operation of the non-volatile memory 4, for example, when the erase process is conducted.

The reset input control circuit 3 receives the BUSY/READY signal from the non-volatile memory 4. The reset input control circuit 3 does not supply, when the BUSY/READY signal is activated, the reset signal RSTEX to the non-volatile memory 4 even if it receives the reset signal RSTEX from the external reset terminal 2.

The command control circuit 5 identifies a command by receiving a command address and a command data. For example, when a fault occurs, the BUSY/READY signal sent from the non-volatile memory 4 is continuously activated and thereby the condition where the non-volatile memory 4 cannot be reset will occur continuously. In this case, the condition where the reset signal is not supplied to the non-volatile memory 4 of the reset input control circuit 3 is forcibly cancelled to reset the non-volatile memory 4 by supplying the command signal to instruct the reset to the reset input control circuit 3 from the command control circuit 5.

FIG. 4 illustrates a first timing chart of the semiconductor device in the present invention. While the BUSY/READY signal is activated, reset of the flash memory 4 is invalidated with the reset input control circuit 3 even when the reset signal is supplied to the external reset terminal 2 and thereby the reset process is not conducted for the flash memory 4.

FIG. 5 illustrates a second timing chart of the semiconductor device in the present invention. In the timing chart of FIG. 5, the process of the command control circuit 5 is added to the timing chart of FIG. 4.

Like the timing chart of FIG. 4, reset of the flash memory 4 is invalidated with the reset input control circuit 3 even when the reset signal is supplied to the external reset terminal 2 and thereby the reset process is not executed to the flash memory 4. However, when the predetermined period has passed from supply of the reset signal to the external reset terminal 2, the command address and command data for instructing the reset are supplied to the command control circuit 5. The command control circuit 5 generates the command signal for instructing the reset on the basis of the command address and command data and then supplies the command signal to the reset input control circuit 3. The reset input control circuit 3 supplies the reset signal RSTEX to the flash memory 4 on the basis of the command signal to reset the flash memory 4. As explained above, continuation of the condition where the flash memory 4 is not reset can be prevented by generation of the command signal for forcible reset.

The semiconductor device in the present invention can provide the following effects.
(1) Reset of the flash memory during the erasing operation is inhibited and over-erase of the flash memory can be prevented.
(2) Since the existing control signal of the flash memory is used, reset during the erase operation of the flash memory can be inhibited with a simplified circuit structure.
(2) Since the means for forcibly resetting the flash memory which is inhibited for reset during the erase operation is provided, continuation of the condition where reset is impossible due to a fault in the flash memory can be prevented.

### BRIEF DESCRIPTION OF THE DRAWINGS

FIG. 1 is a diagram illustrating an electronic device of the related art.

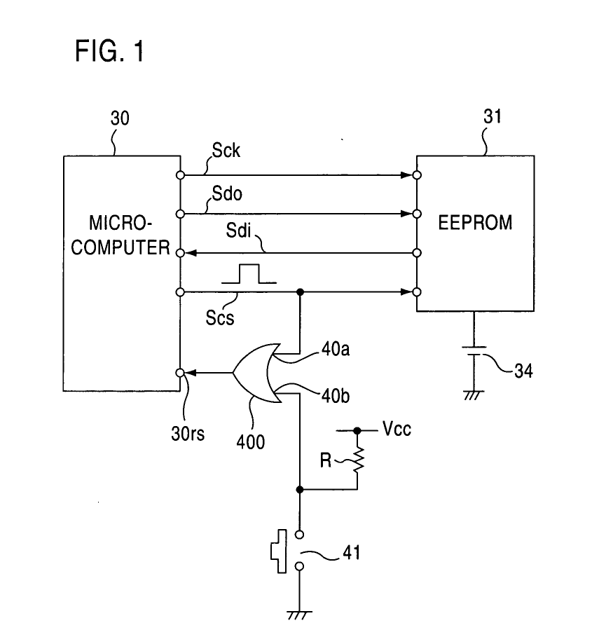

FIG. 2 is a diagram illustrating an information processing apparatus of the related art.

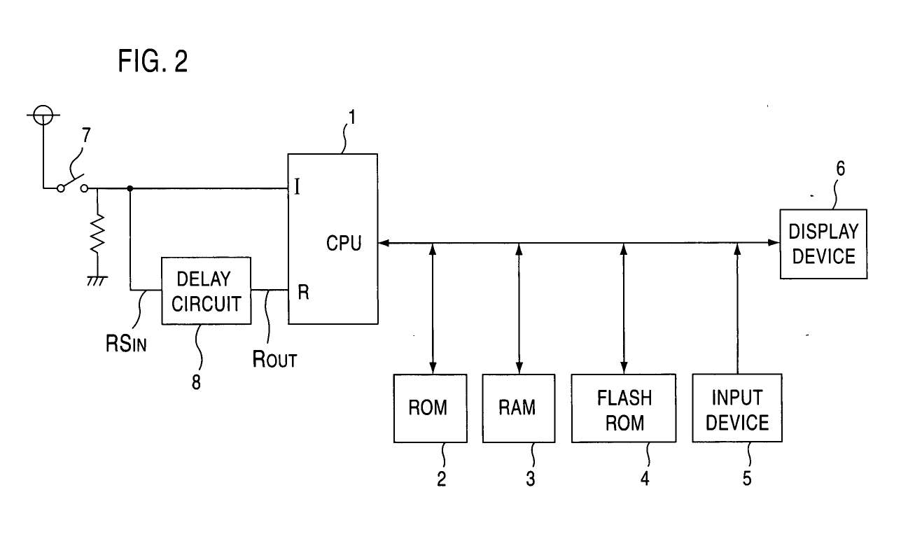

FIG. 3 is a diagram illustrating the principle of the present invention.

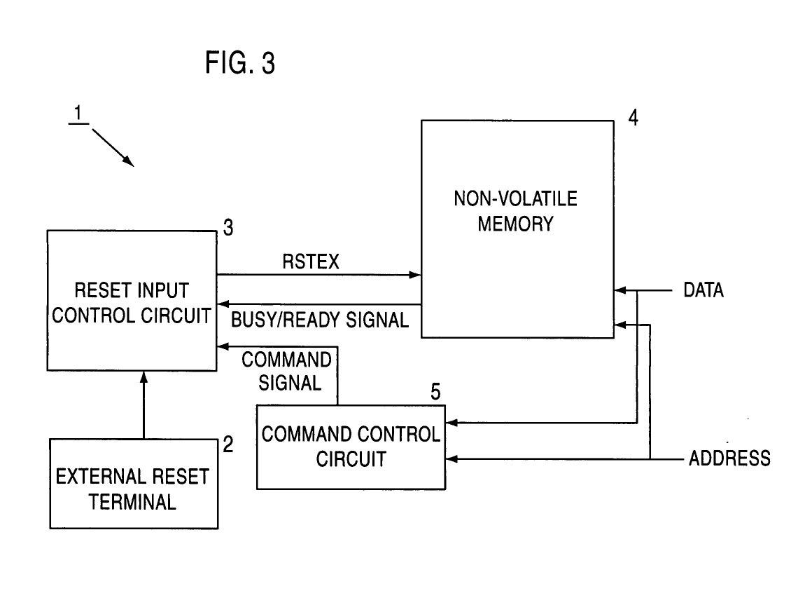

FIG. 4 is a diagram illustrating a first timing chart of the semiconductor device in the present invention.

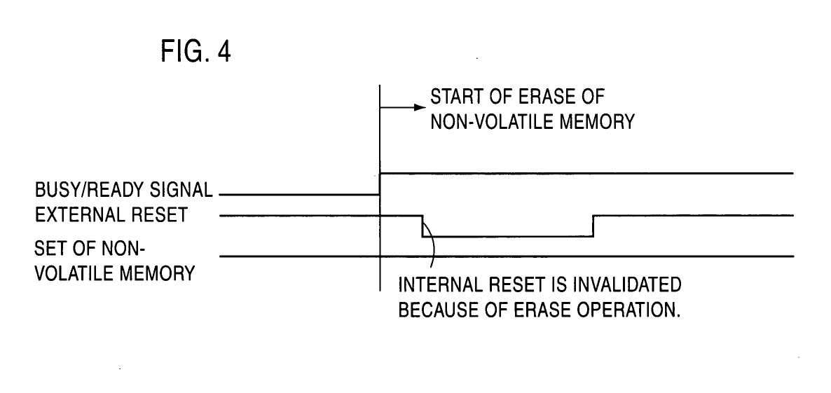

FIG. 5 is a diagram illustrating a second timing chart of the semiconductor device in the present invention.

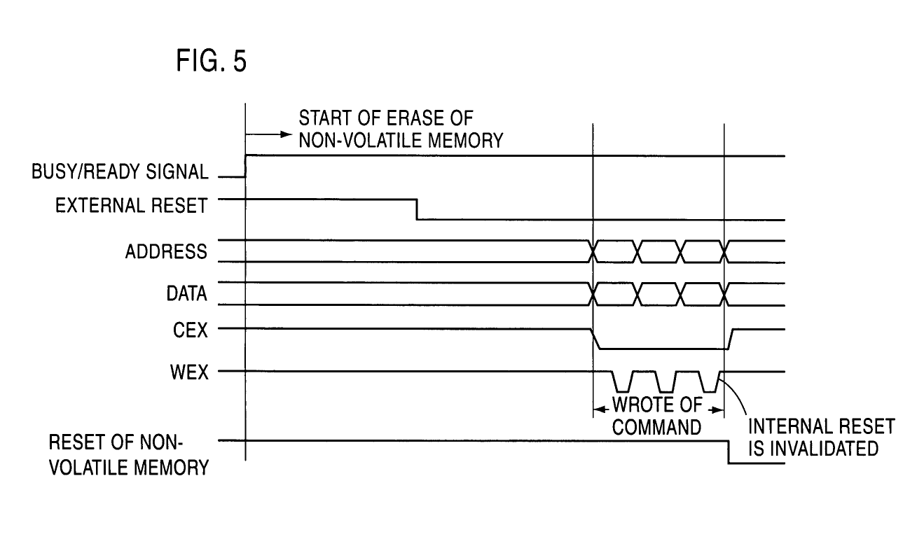

FIG. 6 is a diagram illustrating a first embodiment of the present invention.

FIG. 7 is a diagram illustrating a first example of a reset input control circuit.

FIG. 8 is a diagram illustrating an example of a command control circuit.

FIG. 9 is a diagram illustrating a second embodiment of the present invention.

FIG. 10 is a diagram illustrating a semiconductor device comprising an external timer circuit.

FIG. 11 is a diagram illustrating a second example of the reset input control circuit.

### BEST MODE FOR CARRYING OUT THE EMBODIMENTS

### First Embodiment

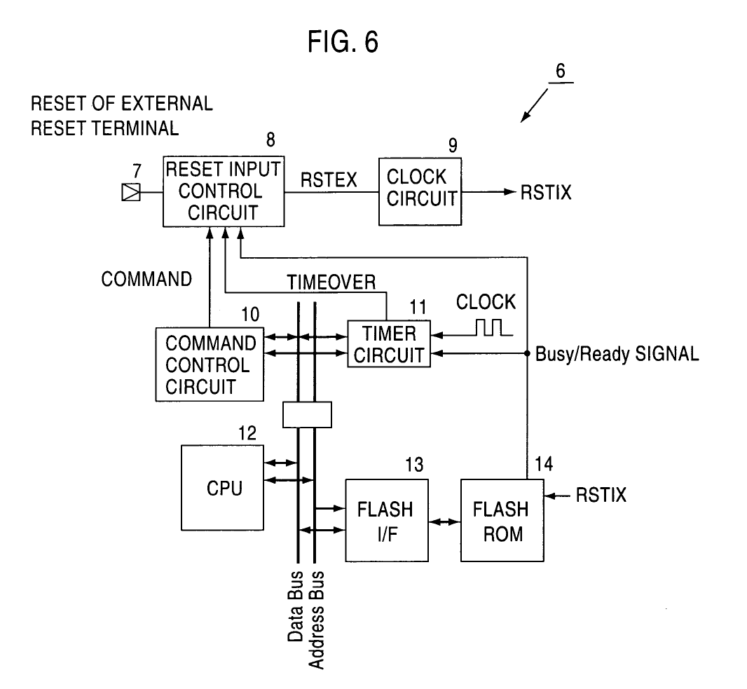

FIG. 6 illustrates a first embodiment of the present invention.

A semiconductor device 6 of the first embodiment in the present invention is structured not to supply the reset signal to a flash ROM 14 when the flash ROM 14 executes the erase process.

The semiconductor 6 is constituted with an external reset terminal 7, a reset input control circuit 8, a command control circuit 10, a timer 11, a CPU 12, a flash I/F 13 (interface), and a flash ROM 14.

The reset input control circuit 8 receives the external reset signal from the external reset terminal 7 and supplies the external reset signal RSTEX to a clock circuit 9.

The clock circuit 9 synchronizes the external reset signal RSTEX from the reset input control circuit 8 to the clock signal and supplies this signal as the internal reset signal RSTEX to an internal circuit including the flash ROM 14.

The flash I/F 13 is arranged among the address bus, data bus and flash ROM 14 to supply the address or data to the flash ROM 14 and transmits the data from the flash ROM 14 to the data bus.

The CPU 12 controls the entire part of the semiconductor device 4. The CPU 12 supplies the write address and write data to the flash ROM 14 to control data write to the flash ROM 14. Moreover, the CPU 12 supplies the read address to the flash ROM 14 to control data read from the flash ROM 14.

The flash ROM 14 is reset on the basis of the internal reset signal RSTEX from the clock signal 9. In addition, the flash ROM 14 supplies the BUSY/READY signal to the reset input control circuit 3 and the timer circuit 11.

The reset input control circuit 8 supervises the BUSY/READY signal supplied from the flash ROM 14. The reset input control circuit 8 is constituted not to supply the external reset signal RESTEX to the clock circuit 9 even when the reset signal is supplied from the external reset terminal 7 while the BUSY/READY signal is being activated. As explained above, the flash ROM 14 is never reset during the erase operation thereof by providing the reset input control circuit 8.

However, it is also thought to occur that the BUSY/READY signal is continuously activated and is never non-activated because of generation of a fault. In this case, the flash ROM 14 cannot be reset even when it is desired, and thereby non-responsive state of the semiconductor device is continued.

In the present invention, following two means are provided to avoid the condition explained above.

The first means is the timer circuit 11. When the predetermined period has passed, forcible reset can be realized by providing the timer circuit 1.

The second means is the command control circuit 10. The forcible reset can also be attained by providing the command control circuit 10 and then supplying the command to instruct the reset state.

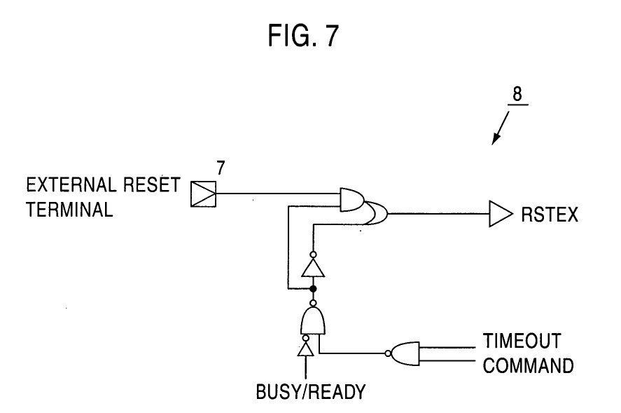

FIG. 7 illustrates a first example of the reset input control circuit.

To the reset input control circuit 8 of FIG. 7, the reset signal from the external reset terminal 7, the BUSY/READY signal from the flash ROM 14, the TIMEOUT signal from the timer circuit 11, and the COMMAND signal from the command control circuit 10 are supplied.

The reset input control circuit 8 activates, when the BUSY/READY signal, TIMEOUT signal and command signal are all not activated (L level signals), the external reset signal RSTEX in response to the external reset signal and sets this signal to the L level (the activated signal becomes L level because the reset signal is set to the negative signal in the first embodiment of the present invention).

When the BUSY/READY signal is activated and becomes the H level and the TIMEOUT signal and command signal are not activated (L level signals), the reset input control circuit 8 does not activate the external reset signal RSTEX and maintains this signal to the H level.

Here, when any of the TIMEOUT signal and the COMMAND signal is activated and is set to the H level, the external reset signal RSTEX is activated and is set to the L level, even when the BUSY/READY signal is activated and is set to the H level.

As explained above, the reset input control circuit 8 does not activate the external reset signal RSTEX when the BUSY/READY signal is activated, but activates the external reset signal RSTEX when any of the TIMEOUT signal and the COMMAND signal is activated.

The first means explained above will be explained.

The timer circuit 11 as the first means for avoiding the condition reset is impossible because of generation of a fault is driven when the BUSY/READY signal supplied from the flash ROM 14 is activated and starts the count of internal clock. When the count value exceeds the predetermined value, the timer circuit 11 supplies the TIMEOVER signal to the reset input control circuit. As the predetermined value, the time which is required to erase the particular block in the flash ROM or the like is set and the reset process is commenced at the timing when the erase process is completed. The reset input control circuit 8 starts, upon supply of the TIMEOVER signal, supply of the external reset signal RSTEX in the suspended state to the clock circuit 9. The clock circuit 9 supplies the internal reset signal RSTEX to the flash ROM 14 to start the reset process to the flash ROM 14 based on the internal reset signal RSTEX. Since the forcible reset is conducted with the timer circuit 11 as explained above, it is possible to eliminate the state that the flash ROM 14 cannot be reset.

Since the timer circuit is provided within the ordinary circuit of a microcomputer or the like, the first means can be provided, without addition of a new timer, by utilizing the existing timer circuit.

The second means explained above is explained below.

The command control circuit 10 as the second means for avoiding the state where the reset is impossible is connected to the address bus and data bus. To the command control circuit 10, the command address and command data for instructing reset are supplied from the CPU 12 via the address bus and data bus. The command control circuit 10 decodes the command address and command data and outputs the command signal to instruct start of reset to the reset input control circuit 8.

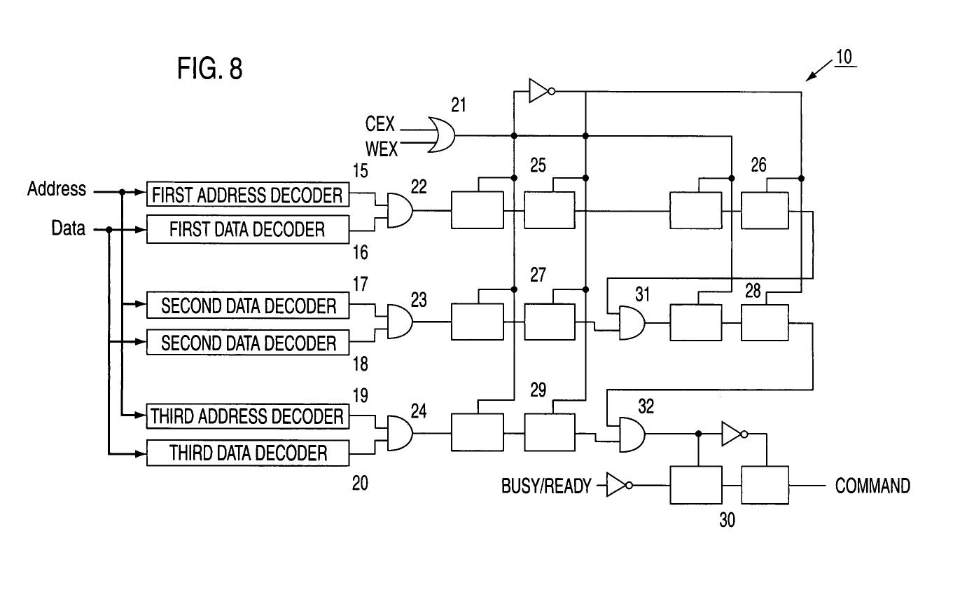

FIG. 8 illustrates an example of the command control circuit.

The command control circuit 10 of FIG. 8 is constituted to activates, when the reset is surely executed because the command to instruct reset is supplied for three times, the command signal and supplies the command signal to the reset input control circuit 8. In the command control circuit 10 of FIG. 8, the command is verified by supplying the command for three times, but such number of times is not limited three and it is enough when the number of times for verifying the command is set.

The command control circuit 10 is constituted with an OR circuit 21 to which the chip enable signal CEX and write enable signal WEX are supplied, three pairs 15 to 20 of the address decoder to which the command address is supplied and the command decoder to which the command data is supplied, the AND circuits 22 to 24 arranged at the output of each pair, first to fifth latch circuit groups 25 to 29 for conducting the latch operation with the output signal from the OR circuit 21, the six latch circuit group 30 for latching the BUSY/READY signal, and the AND circuits 31 to 32 arranged among the first to fifth latch circuit groups.

A plurality of latch groups 25 to 29 latch the signals to the latch circuit of the preceding stage when the chip enable signal CEX and write enable signal WEX are all activated and are set to the H level. When the chip enable signal CEX and write enable signal WEX are all non-activated and are set to the L level, these latch groups latch the signal latched to the latch circuit of the preceding stage to the latch circuit of the subsequent stage.

The first command address and the first command data are supplied to the first address decoder 15 and the data decoder 16 and decoded therein and finally supplied to the AND circuit 22. When the first command address and the first command data have contents assumed by the command control circuit 10, namely when it is the command to instruct the reset, the AND circuit 22 outputs the first signal of the H level.

Thereafter, the first signal is then supplied to the first latch circuit group 25.

The second command address and the second command data are supplied to the second address decoder 17 and the second data decoder 18 and these are decoded therein and finally supplied to the AND circuit 23. When the second command address and the second command data have the contents assumed by the command control circuit 10, namely when it is the command to instruct the reset, the AND circuit 23 outputs the second signal of the H level.

Thereafter, the second signal is supplied to the third latch circuit group 27.

When the second signal is latched with the third latch circuit group 27, the first signal latched by the first latch circuit group 25 is then latched with the second latch circuit group 26.

The third command address and the third command data are supplied to the third address decoder 19 and the third data decoder 20 and decoded therein and finally supplied to the AND circuit 24. When the third command address and the third command data have contents assumed by the command control circuit 10, namely it is the command to instruct the reset, the AND circuit 24 outputs the third signal of the H level.

Thereafter, the third signal is supplied to the fifth latch circuit group 29.

When the third signal is latched with the fifth latch circuit group 29, the first signal latched with the second latch circuit group 26, the second signal latched with the third latch circuit group 27 and the fourth signal AND-processed with the AND circuit 31 are latched with the fourth latch circuit group 28.

The third signal latched with the fifth latch circuit group 29 and the fourth signal latched with the fourth latch circuit group 28 are supplied to the AND circuit 32 to output the fifth signal.

As explained above, the AND circuits 31, 32 perform the AND processes of three information pieces of \textcircled{1} first command address and second command data, \textcircled{2} second address and second command data, \textcircled{3} third command address and third command data. The fifth signal indicates whether \textcircled{1}, \textcircled{2} and \textcircled{3} are matched or not. When these are matched, the signals become H level. If these are not matched, the signals become L level. With the fifth signal of H level indicating matching of three commands, the BUSY/READY signal is supplied to the sixth latch circuit group 30 and is then outputted from the command control circuit 10 as the command signal.

The TIMEOVER signal outputted from the timer 11 as the first means and the command signal outputted from the command control circuit 19 as the second means are supplied to the reset input control circuit 8 as illustrated in FIG. 7. The reset input control circuit 8 activates, when any of the TIMEOVER signal and command signal is activated, the external reset signal RSTEX and then supplies it to the clock circuit 9. The clock circuit 9 generates the internal reset signal TSTIX based on the external reset signal RSTEX and supplies it to the flash ROM 14. The flash ROM 14 is reset on the basis of the internal reset signal RSTEX.

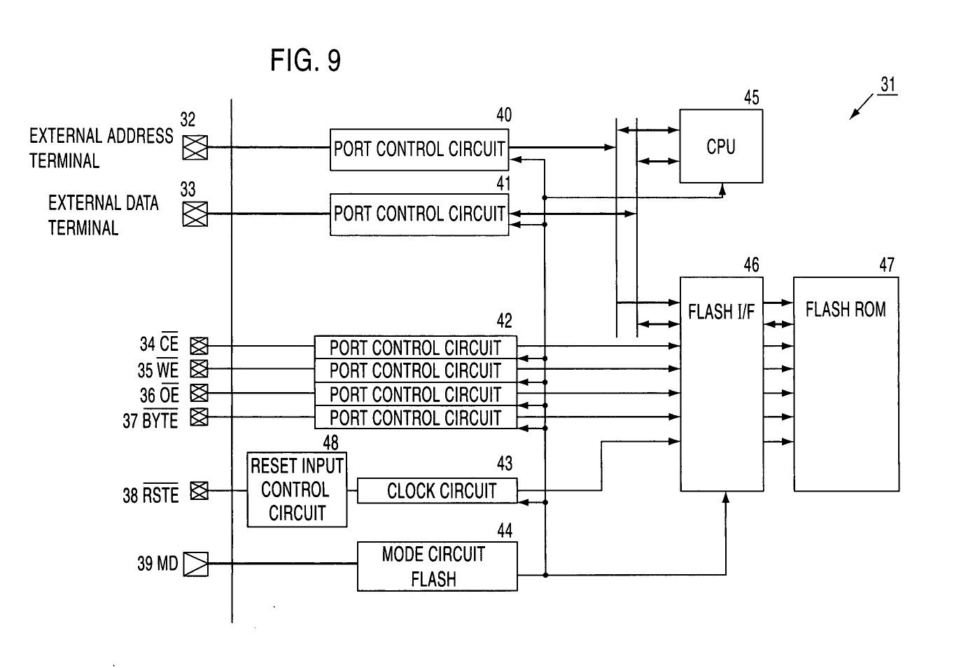

FIG. 9 illustrates a second embodiment of the present invention.

The semiconductor device 31 of the second embodiment of the present invention is constituted not to supply the reset signal to the flash ROM 47 like the first embodiment of the present invention when the flash ROM 47 executes the erase process.

The semiconductor device 31 of the second embodiment of the present invention is different from the semiconductor device 6 of the first embodiment of the present invention in the point that the timer circuit and command control circuit are not provided within the semiconductor device and an external timer circuit not illustrated in FIG. 9 is provided. The flash ROM 47 of the semiconductor device 31 of the second embodiment of the present invention is set to the mode which is controlled in direct from the external side.

Accordingly, it is impossible to use the timer circuit and command control circuit which are controlled with the CPU provided in the semiconductor device as the means for eliminating the condition where the reset is impossible. Therefore, the external timer circuit which may be controlled from the external side of the semiconductor device is provided as the means for avoiding the condition where reset is impossible.

The semiconductor device 31 is constituted with an external address terminal 32, an external data terminal 33, a chip enable terminal/CE 34, a write enable terminal/WE 35, a read enable terminal/OE 36, a byte setting terminal/BYTE 37, an external reset terminal/RSTE 38, a mode terminal MD 39, port control circuits 40 to 42, a clock circuit 43, a mode circuit 44, a CPU 45, a flash I/F 46, and a flash ROM 47.

To the external address terminal 32, an address is supplied from the external side and the address supplied is then supplied to an internal circuit via the port control circuit 40.

To the external data terminal 33, external data is supplied and the data supplied is then supplied to the internal circuit via the port control circuit 41. Moreover, to the external data terminal 33, the data from the internal circuit is supplied via the port control circuit 41 and thereby the data supplied is outputted to the external side.

To the chip enable terminal/CE 34, the chip enable signal is supplied from the external side and the chip enable signal supplied is then supplied to the internal circuit via the port control circuit 42.

To the write enable terminal/WE 35, the write enable signal is supplied from the external side and the write enable signal supplied is then supplied to the internal circuit via the port control circuit 42.

To the read enable terminal/OE 36, the read enable signal is supplied from the external side and the read enable signal supplied is then supplied to the internal circuit via the port control circuit 42.

To the byte setting terminal/BYTE 37, the byte setting signal indicating the width of byte is supplied and the byte setting signal supplied is then supplied to the internal circuit via the port control circuit 42. With the byte setting signal, the data width, for example, can be switched to 16 bits or 8 bits.

To the external reset terminal/RSTE 38, the reset signal is supplied from the external side and the reset signal supplied is then supplied to the internal circuit via the reset input control circuit 48 and clock circuit 43.

The reset input control circuit 48 has the function identical to that of the reset input control circuit of the first embodiment of the present invention. Namely, this reset input control circuit 48 is constituted not to supply the reset signal to the clock circuit 9 even when the reset signal is supplied from the external reset terminal/RSTE while the BUSY/READY signal outputted from the flash ROM 47 is activated.

The clock circuit 43 has the function identical to that of the clock circuit 9 illustrated in FIG. 6 to generate the internal reset signal obtained by synchronizing the external reset signal to the internal clock and then supply this internal reset signal to the internal circuit.

To the mode terminal MD 39, the mode setting signal is supplied and the mode setting signal supplies is then supplied to the internal circuit via the mode circuit 44. With the mode setting signal, the control method of the flash ROM 47 can be designated. For example, the single flash mode or one chip mode can be set through the switching operation. When the single flash mode is set, the flash ROM can be controlled in direct from the external side. Namely, the address bus and data bus in the semiconductor device (or chip) can be freed from the CPU 45 or the like and the data can be written in direct to the flash ROM 47 by designating the write address and write data to the external address terminal and external data terminal. Accordingly, the data can be read in direct from the flash ROM 47 by designating the read address to the external terminal. The single flash mode is used for testing the flash ROM 47 or writing the information and program required for system operations to the flash ROM 47 before the system is set up. When the one chip mode is set, the flash ROM 47 is controlled with the CPU (or chip) in the semiconductor device and the flash ROM 47 cannot be controlled from the external side. Namely, the data is written into the flash ROM 47 on the basis of the data write command from the CPU and thereby the data can be read from the flash ROM 47 on the basis of the data read command from the CPU. In the semiconductor device 31 in the second embodiment, the single flash mode is set as the mode setting signal. Therefore, the flash ROM 47 is not controlled with the CPU 45 but with the signals from the external address terminal 32 and external data terminal.

The flash I/F 46 is the interface provided between the flash ROM 47 and the other structural elements of the internal circuit.

Since the single flash mode is set as the mode setting signal in the flash ROM 47, the flash I/F 46 supplies in direct the input to the flash Rom 47 through the external address terminal 32 and external data terminal 33 and then supplies in direct the output from the flash ROM 47 to the external data terminal 33.

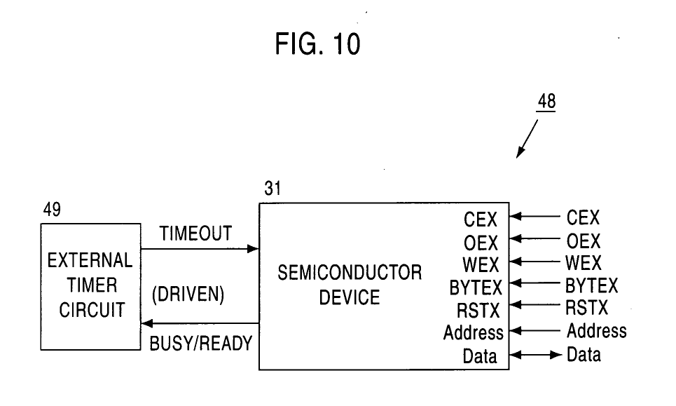

As explained above, the flash ROM 47 of the semiconductor device 31 in the second embodiment of the present invention is controlled in direct from the external side. Therefore, it cannot use the timer circuit in the semiconductor device controlled by the CPU 45 as the means for controlling reset of the flash ROM 47. Reset of the flash ROM 47 must be controlled with the external circuit. For this reason, the semiconductor device 31 of the second embodiment in the present invention is provided with the external timer circuit as illustrated in FIG. 10.

FIG. 10 illustrates the semiconductor device 48 provided with the external timer circuit.

In FIG. 10, the semiconductor device 31 illustrated in FIG. 9 is provided with a timer circuit.

To the external timer circuit 49 illustrated in FIG. 10, the BUSY/READY signal outputted from the flash ROM 47 comprised in the semiconductor device 31 is supplied. When the BUSY/READY signal is activated, the external timer circuit 49 is driven to start the count operation. When it counts up to the predetermined value, it activates the TIMEOUT signal and then supplies this signal to the reset input control circuit 49 within the semiconductor device 31. As the predetermined value, for example, the time required for erasing the particular block in the flash ROM or the like is set and the reset process is commenced assuming the time when the erase process is completed.

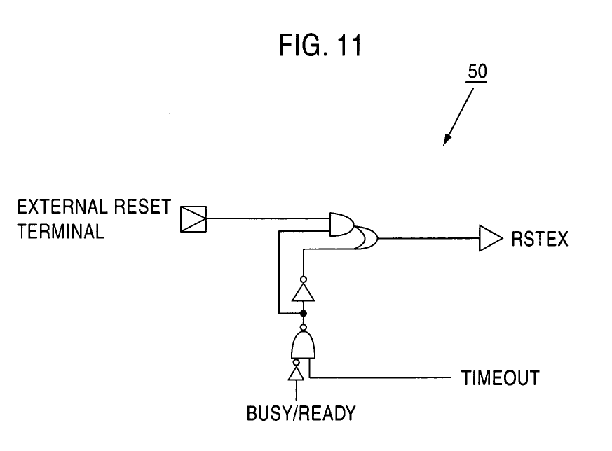

FIG. 11 illustrates a second example of the reset control input circuit.

The reset control input circuit 50 illustrated in FIG. 11 is identical to the reset control input circuit of the second embodiment in the present invention.

The reset control input circuit 50 illustrated in FIG. 11 is formed in the structure almost identical to that of the reset control input circuit of the semiconductor device 6 of the first embodiment in the present invention but is different therefrom in the point that the command signal is not supplied thereto. As explained above, since the flash ROM 47 is set to the mode which is controlled in direct from the external circuit, the command is not supplied because the command control circuit to be controlled by the CPU cannot be used.

When the BUSY/READY signal and the TIMEOUT signal are all not activated (set to the L level), the reset input control circuit 50 activates the external reset signal RSTEX responding to the reset signal from the external circuit and then supplies this external reset signal RSTEX as the L level signal to the clock circuit 43.

When the BUSY/READY signal is activated to become H level and the TIMEOUT signal is not yet activated (remaining as the L level signal), the reset input control circuit 50 does not activate the external reset signal RSTEX and supplies this signal to the clock circuit 43 while it is remained as the H level.

Here, when the TIMEOUT signal is activated to become H level, the reset input control circuit 48 activates the external reset signal RSTEX to become L level, without relation to the BUSY/READY signal which is activated to become the H level, and then supplies this L level signal to the clock circuit 73.

As explained above, when the BUSY/READY signal is activated, the reset input control circuit 50 does not activate the external reset signal RSTEX but activates the external reset signal RSTEX when the TIMEOUT signal is activated.

Here, is assumed that the single flash mode is set to the semiconductor 31 in the second embodiment of the present invention. However, any of the single flash mode or one chip mode can be set through the switching operation by arranging the timer circuit and command control circuit comprised in the semiconductor device of the first embodiment in the present invention into the semiconductor device 31.

Industrial Field of Utilization

According to the semiconductor device of the present invention, following effects can be achieved.
(1) Reset during the erase operation of the flash memory is inhibited and over-erase of flash memory can be prevented.
(2) Since the existing control signal of the flash memory is used, reset in the erase operation of flash memory can be inhibited with a simplified structure.
(3) Since a means for forcibly resetting the flash memory which is inhibited in the reset during the erase operation is provided, continuation of the state where reset is impossible due to a fault in the flash memory can be prevented.
(4) Flexible use can be assured because reset during the erase operation of the flash ROM can be inhibited and continuation of the state where reset of the flash ROM is impossible can be prevented corresponding to both single flash mode controlled from the external side and the one chip mode controlled from the internal side.

Because of the effects explained above, the present invention can effectively adapted particularly to a microcomputer employing the flash ROM.

What is claimed is:

1. A semiconductor device comprising:
a non-volatile memory; and
a reset input control circuit for supplying the reset signal to said non-volatile memory, wherein said reset input control circuit does not supply the reset signal to said non-volatile memory when the busy signal outputted from said non-volatile memory is not activated.

2. The semiconductor device according to claim 1 further comprising:
a command control circuit for supplying the command signal to instruct reset to said reset input control circuit.

3. The semiconductor device according to claim 2, wherein said command control circuit outputs said command signal when the data for reset is received for several times.

4. The semiconductor device according to claim 1 further comprising:
a timer circuit which is driven on the basis of said busy signal to output the time-over signal to instruct reset to said reset input control circuit when counting up to the predetermined value.

5. The semiconductor device according to claim 4, wherein said timer circuit is externally provided.

6. The semiconductor device according to claim 2, wherein said reset input control circuit outputs said reset signal to said non-volatile memory when said command signal is inputted.

7. The semiconductor device according to claim 4, wherein said timer circuit outputs said reset signal to said non-volatile memory when said time-over signal is inputted.

8. The semiconductor device according to claim 1 further comprising:
an external terminal for controlling said non-volatile memory.

9. The semiconductor device according to claim 1, wherein said semiconductor device is capable of setting a first mode and a second mode, said non-volatile memory is controlled within said semiconductor device when said first mode is set, said non-volatile memory is controlled from an external circuit when said second mode is set.

10. The semiconductor device according to claim 1 further comprising:
a clock circuit for synchronizing said reset signal to the internal clock.

11. The semiconductor device according to claim 1, wherein said busy signal is activated when the erase process of said non-volatile memory is started.

12. A reset control system comprising:
a CPU;
a non-volatile memory, and
a reset input control unit for supplying the reset signal to said non-volatile memory,
wherein said reset input control unit supplies the reset signal to said non-volatile memory when the busy signal outputted from said non-volatile memory is non-activated, said reset input control unit does not supply said reset signal to said non-volatile memory when the busy signal outputted from said non-volatile memory is activated.

13. The reset control system according to claim 12 further comprising:
a command control unit for supply the command signal to instruct reset to said reset input control unit.

14. The reset control system according to claim 12 further comprising:
a timer unit, responsive to said busy signal, for outputting the time-over signal for reset to said reset input control unit after the predetermined number is counted up.

15. The reset control system according to claim 12 further comprising:
an external terminal for setting the method of controlling said non-volatile memory.

16. The reset control system according to claim 12, wherein said reset control system is capable of setting a first mode and a second mode, said non-volatile memory is controlled with said CPU and when said first mode is set and, said non-volatile memory is controlled from an external circuit when said second mode is set.

17. A memory reset method for resetting a non-volatile memory comprising:
supplying a reset signal supplied from the external side of said semiconductor device to said non-volatile memory when detecting the non-activated state of the busy signal from said non-volatile memory,
not supplying said reset signal to said non-volatile memory when detecting the activated state of the busy signal from said non-volatile memory.

18. The memory reset method according to claim 11, wherein said non-volatile memory is forcibly reset on the basis of the reset instruction when the busy signal outputted from said non-volatile memory is activated.
